(19) United States
(12) Patent Application Publication
(10) Pub. No.: US 2009/0080258 A1
(43) Pub. Date: Mar. 26, 2009

(54) ERASE METHOD IN THIN FILM NONVOLATILE MEMORY

(76) Inventor: Andrew J. Walker, Mountain View, CA (US)

Correspondence Address: MACPHERSON KWOK CHEN & HEID LLP, 2033 GATEWAY PLACE, SUITE 400, SAN JOSE, CA, 95110, US

(21) Appl. No.: 12/211,764

(22) Filed: Sep. 16, 2008

Related U.S. Application Data
(60) Provisional application No. 60/974,429, filed on Sep. 21, 2007.

(51) Int. Cl. G11C 16/14; G11C 16/04

(52) U.S. Cl. 365/185.17; 365/185.29

(57) ABSTRACT

An erase method applicable to dual-gate memory strings has key advantages over erase methods for other thin-film non-volatile memory strings. The advantages include (a) fast erase without any source-to-body short; (b) flexible erase which erases any number of memory cells in a block (i.e., from none to all cells); (c) source voltage may be set to optimize non-selected string channel boosting; and (d) the thickness of the thin-film device's body can be optimized for scalability. The method uses the access devices of the dual-gate memory cells in a memory string to form inversion channels, so as to provide conductive paths between the memory cells to be erased and a node at a more positive voltage than the erase voltage applied to the gate electrodes of the memory devices to be erased.

### CROSS-REFERENCE TO RELATED APPLICATIONS

The present patent application is related to and claims priority of U.S. provisional patent application (“Provisional Application”), entitled “Erase Method in Thin Film Nonvolatile Memory,” Ser. No. 60/974,429, which was filed on Sep. 21, 2007. The present invention is also related to U.S. patent applications (“Copending Applications”), both entitled “Dual Gate Device and Method,” Ser. Nos. 11/197,462 and 11/548,231, filed on Aug. 3, 2005 and Oct. 10, 2006, respectively.

The Provisional Application and the Copending Applications are hereby incorporated herein by reference in their entireties.

### BACKGROUND OF THE INVENTION

1. Field of the Invention

The present invention relates to erase methods in non-volatile memories. In particular, the present invention relates to erase methods in dual-gate memory cells organized into memory strings.

2. Discussion of the Related Art

Thin-film transistors have been proposed as building blocks for three dimensionally (3-D) integrated non-volatile memory circuits. Examples of such use have been discussed in (a) the article “3D-TFT SONOS Memory Cell for Ultra-High Density File Storage Applications” (the “Walker Article”) by Walker et al., presented in the Symposium on VLSI Technology, Kyoto 2003; and (b) the article “Three Dimensionally Stacked NAND Flash Memory Technology Using Stacking Single Crystal Si Layers on ILD and TANOS Structure for Beyond 30 nm Node” (the “Jung Article”) by Jung et al., presented in the International Electronic Devices Meeting (IEDM), 2006.

The Walker Article reported results of making a nonvolatile memory cell using a single-gated thin-film transistor. The Jung Article shows NAND memory strings that consist of a first layer of memory cells made in the bulk of a silicon wafer and a second layer of memory cells built on top of and isolated from the first layer of memory cells. The second layer of memory cells includes single-gated thin-film transistors formed in a thin layer of crystalline silicon. The memory component of both memory cell layers is a stack known as TANOS which consists of a tantalum nitride gate conductor in contact with a layer of aluminum oxide dielectric. The aluminum dielectric layer is deposited on top of a silicon nitride layer, which in turn is deposited on top of a silicon dioxide layer.

Erasing non-volatile memory cells has arisen as a problem in series-connected thin-film transistors that act as non-volatile memory devices (e.g., the NAND memory string configuration shown in the Jung Article). In a regular NAND non-volatile memory string formed in the bulk of a silicon wafer, an erase operation of the memory string is carried out, for example, by grounding all word lines and raising a positive voltage of the p-type well in which the memory string is provided. (The same P-type well may include other NAND strings also). In this manner, many memory cells are erased simultaneously. However, in a NAND string of thin-film transistors, as explained in the Jung Article, the body of the transistors in the NAND string is placed above the devices in the bulk of the silicon wafer and is therefore floating. Consequently, only one cell per NAND string can be erased at any one time, since a pass voltage must be applied to the gates of other devices in order to connect the channel of the selected memory cell to ground. A large negative voltage is then applied to the gate electrode (i.e., word line) to the selected memory cell. Such a memory cell by memory cell erase operation is very slow for practical use.

The Jung Article teaches electrically shorting the source connection of the NAND memory strings to their body by providing a specialized contact that metallically connects a source region—an N+ doped region—with the active silicon-on-insulator region that is typically doped to a low level with a p-type dopant (e.g., boron). This special common source line contact connects in one block all the N+ source regions and p-type active regions. FIG. 3 of the Jung Article is reproduced herein as FIG. 4. As shown in FIG. 4, the 3D stacked structure shows a common source line contact (“CSL contact”, shown to the right of the “GSL” select devices) shorting corresponding N+ regions in the first and second device layers with the p-type body of the thin film devices (i.e., the second or upper device layer). The CSL contact penetrates the thin film of the second device layer to reach a corresponding N+ region in the first device layer. A similar bit line contact (on the left of the “SSL” select devices) extends from a bit line and penetrates through (next to the SSL devices) to an N+ region in the first device layer. However, the bit line contact does not short the N+ region to the body of the thin film because the bit line contact uses N+ doped polysilicon as plug material, rather than metal). Therefore, a P/N diode is formed between the CSL contact and the bit line contact in all bit lines where the p-type body is connected to the CSL contact and the N+ regions are connected to the bit line contact. Consequently, the CSL contact cannot be applied a voltage that is more than ˜0.6V higher relative to the bit line contact without resulting in forward-biased diodes. However, a common method for program inhibition in a non-selected NAND string, typically referred to as “capacitive boosting,” involves raising the voltage of the CSL by several volts relative to the grounded bit lines in a selected NAND string. The positive CSL voltage reduces a leakage current from the channel region to the CSL in the memory device having the capacitively boosted voltage. The leakage current reduces the efficiency of the boosting. Capacitive boosting, however, is not possible in the memory strings of the Jung Article, as illustrated in FIGS. 5 and 6.

FIG. 5, reproduced from FIG. 11 (b) of the Jung Article¹, shows an erase operation for the memory cells in the second device layer (i.e., the thin film), when the p-type body of the thin-film devices is not shorted to the CSL. Under the conditions of FIG. 5, any memory cell to be erased is connected through inversion channels to the grounded nodes (i.e., the CSL and the bit lines) while a large negative voltage (shown as −18 volts) is applied to the gate electrode of the memory cell to be erased. Because the method requires other memory devices to provide the inversion channels, simultaneously erasing of multiple memory cells is practically impossible (or at least requiring a prohibitively long time). ¹ Incidentally, the descriptions in the Jung Article for its FIGS. 11(a) and 11(b) appear to have been reversed.

FIG. 6, reproduced from FIG. 11(a) of the Jung Article, shows an erase operation for these memory cells in the second device layer, when the p-type body of the thin-film devices is connected to the CSL contact. Under the conditions of FIG. 6, a whole block of memory cells can be erased simultaneously.

There are several disadvantages associated with the erase operation of FIG. 6:
(1) The CSL contact must remain close to the ground reference during a programming operation and cannot be taken to a positive voltage (e.g., 3V or above) because a positive source line voltage would require the same voltage be placed on the bit line contact in the selected memory string. Otherwise, a forward biased diode (i.e., the p-type active region and the N+ bit line contact) would result. Such a positive bias on the selected string's bit line contact would result in a correspondingly higher programming voltage to be applied to the memory cell to be programmed. Generating such a high voltage in the memory string is undesirable.
(2) Maintaining the CSL at close to ground potential during programming results in a large voltage drop in the non-selected NAND string between the capacitively boosted channel and the grounded CSL across the length of the source line select device. A leakage current may develop to cause a droop in the boosted voltage in a non-selected string. The droop in voltage can result in program disturb. To limit the leakage current, the gate electrode for the select device must be longer than the gate electrodes of the memory cells, thereby resulting in a bigger chip area. The Jung Article teaches applying a negative voltage to the gate electrode of the select device. However, this approach may lead to other leakage effects (e.g., gate-induced drain leakage (GIDL)).
(3) Shorting the source N+ region to the active p-type semiconductor region is accomplished by providing the CSL contact that penetrates through to the active p− region. This approach requires the active silicon layer of the thin-film devices to be thicker than the source N+ junction depths to provide sufficient active p− material to contact. Consequently, the thicknesses of the active silicon regions of thin film devices—an important parameter for good scalability—cannot be freely adjusted.

Dual-gate devices achieve high density integrated circuits (e.g., non-volatile memory devices). Examples of dual-gate devices and their uses are found in the Copending Applications that are incorporated by reference above.

### SUMMARY OF THE INVENTION

According to one embodiment of the present invention, the non-memory or access devices in each dual-gate memory string connect the memory devices of the memory string and their local active regions to either the source line or the bit line (or both), so that an erase voltage can be applied simultaneously across the memory device or devices to be erased.

An erase method of the present invention is applicable to dual-gate memory strings. Such a method has key advantages over erase methods for other thin-film non-volatile memory strings. The advantages include (a) fast erase without any source-to-body short; (b) flexible erase which erases any number of memory cells in a block (i.e., from none to all memory cells in the block); (c) source voltage may be set to optimize non-selected string channel boosting; and (d) the thickness of the thin-film device's body can be optimized for scalability. The method uses the access devices of the dual-gate memory cells in a memory string to form inversion channels, so as to provide conductive paths for the memory cells to be erased to a node at a more positive voltage than the erase voltage applied to the gate electrodes of the memory devices to be erased.

The present invention is better understood upon consideration of the detailed description below in conjunction with the drawings.

### DESCRIPTION OF THE DRAWINGS

FIG. 1 is a cross-section of dual-gate memory cell 100 formed by a memory device and a non-memory or access device.

FIG. 2 is a graphical representation 200 of a dual-gate device, indicating gate electrode 201 of the memory device, and gate electrode 202 of the access device, with source and drain connections 203 and 204.

FIG. 3 shows memory strings 501 and 502 each formed out of dual-gate memory cells provided between a dual-gate select device on each end of the string.

FIG. 4 is a reproduction of FIG. 3 in the Jung Article.

FIG. 5, reproduced from FIG. 11(b) of the Jung Article, shows an operation for erasing the memory cells in the second device layer (i.e., the thin film), if the p-type body were not shorted to the CSL contact.

FIG. 6, reproduced from FIG. 11(a) of the Jung Article, shows an operation for erasing memory cells in the second device layer, when the p-type body of the thin-film devices are connected to the CSL contact.

FIG. 7 illustrates an operation for erasing a memory cell in a dual-gate memory string, in accordance with one embodiment of the present invention.

### DETAILED DESCRIPTION OF THE PREFERRED EMBODIMENT

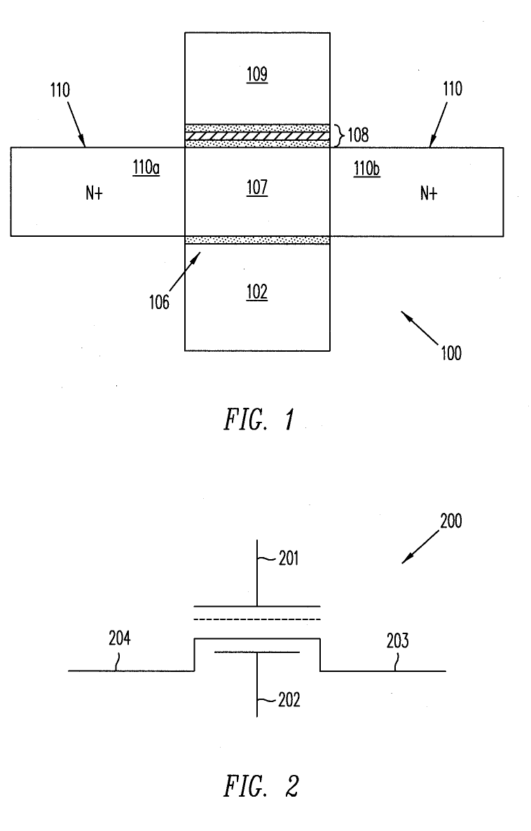

FIG. 1 is a cross-section of dual-gate memory cell 100 formed by a memory device and a non-memory device (also, referred to as an “access device”). As shown in FIG. 1, the access device includes gate dielectric 106 and gate electrode 102 and the memory device includes gate dielectric stack 108 and gate electrode 109. The memory and access devices share source and drain regions 110 and active region 107. Although shown having the memory device formed above the access device, these device may be formed in the reverse order—i.e., with the memory device formed underneath the access device. FIG. 2 is a graphical representation 200 of a dual-gate device, indicating gate electrode 201 of the memory device, and gate electrode 202 of the access device, with source and drain connections 203 and 204.

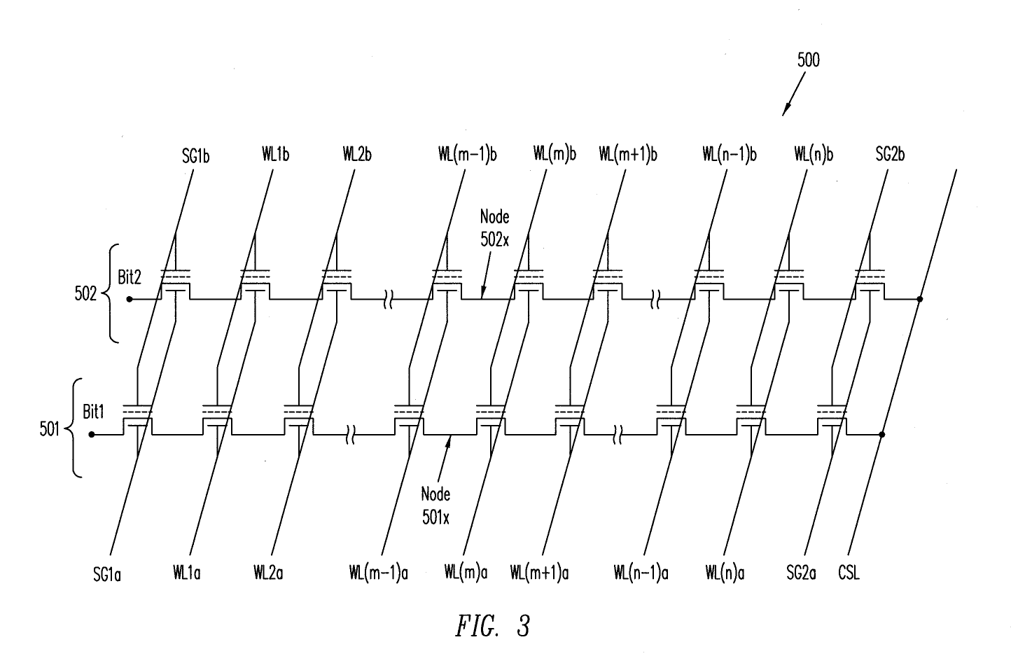

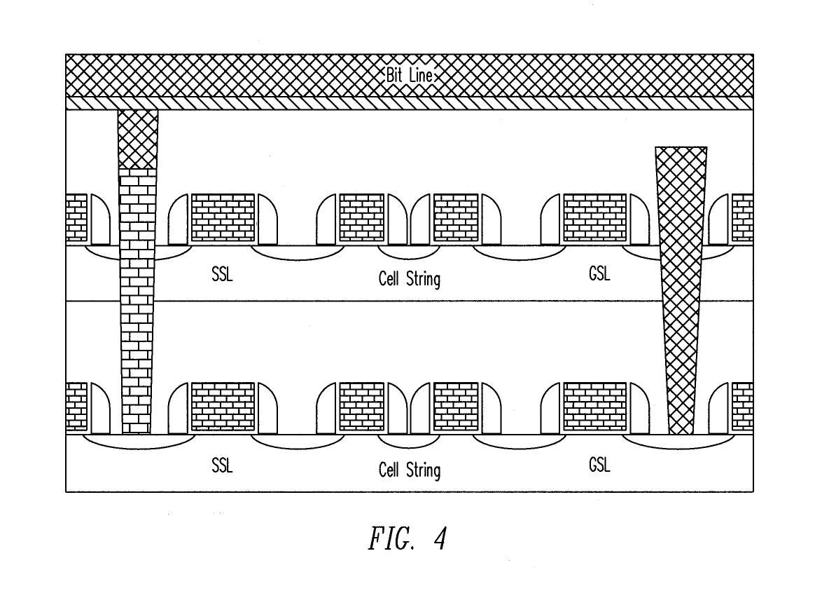

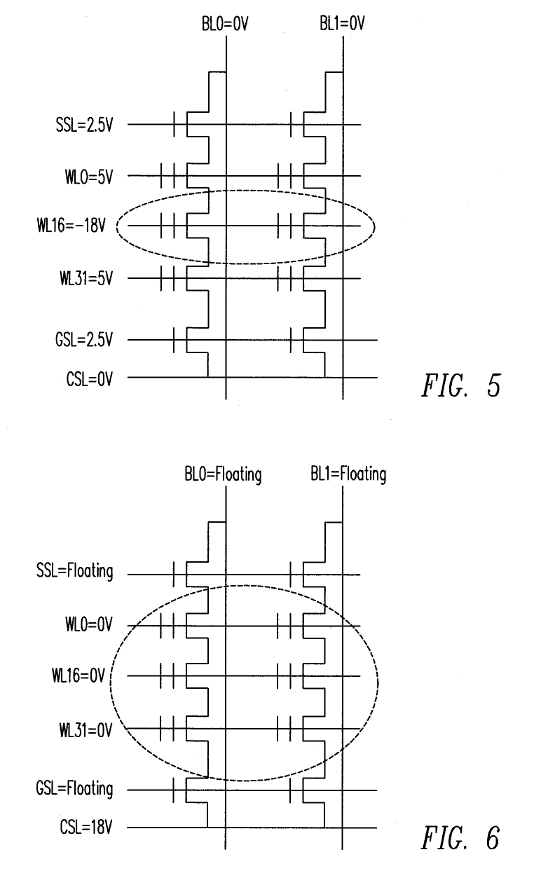

FIG. 3 shows memory strings 501 and 502 each formed out of serially connected dual-gate memory cells provided between dual-gate select devices provided at the ends of the memory string. The select devices connect the memory cells to the bit line and the common source line. Although FIG. 3 shows only a single select device at each end of the memory string, other embodiments may have additional select devices at each end.

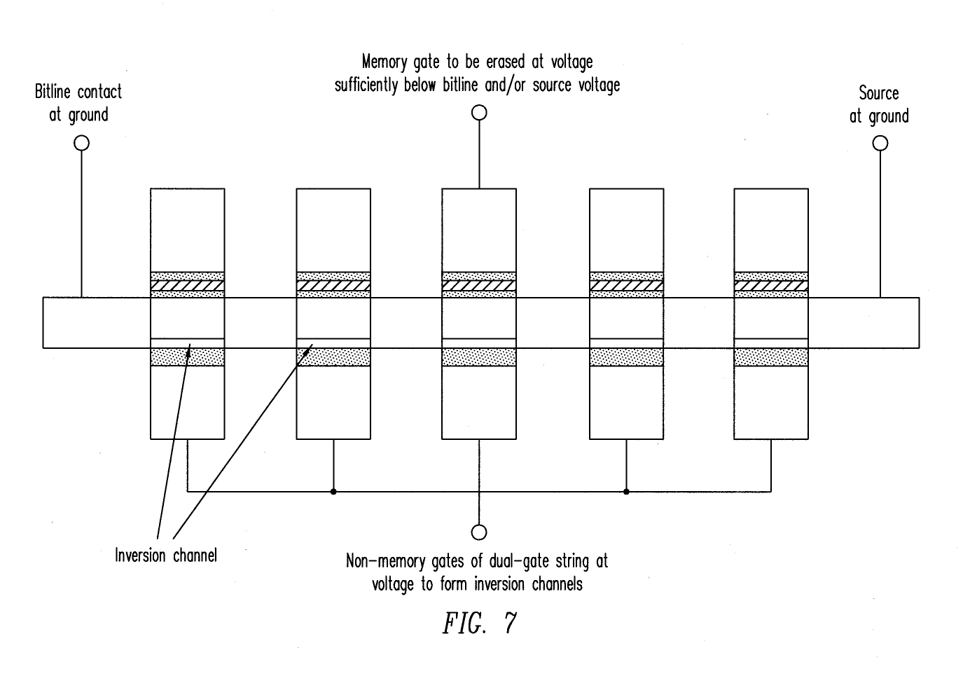

Using its access devices to connect the memory device or devices to be erased to a node at a lower voltage, a memory string of dual-gate memory cells overcomes the disadvantages of the prior art. FIG. 7 illustrates an erase operation for a memory cell in a dual-gate memory string, in accordance with one embodiment of the present invention. As shown in FIG. 7, inversion channels are formed in the accesses devices and the select devices of the dual-gate memory string, so that the source region, the drain region, and the body region of any memory cell to be erased are connected to its bit line, source line, or both. The bit line and source line are held at a sufficiently positive voltage (e.g., the ground reference) relative to the erase voltage (e.g., a negative voltage) on the gate electrode (i.e., word line) of the memory cell to be erased. At any given time, any number of memory cells in the memory string may be simultaneously erased by applying the erase voltage to their respective gate electrodes.

The erase operation illustrated in FIG. 7 has the advantage of flexibility. Specifically, a block of dual-gate memory strings share common word lines that control the gate electrodes of the memory devices in the block. Therefore, any number of cells may be erased simultaneously—i.e., from none (when all word lines are applied the same potential as all the bit line connections, all the source line connections or both) to all memory devices in the block (when all word lines are applied the negative erase potential, while all bit line connections, all source line connections, or both are at ground reference). A single memory device in a single selected memory string may also be erased by maintaining its bit line, its source line, or both, at ground potential, while the word line controlling the memory device is maintained at the negative erase potential, and while all other word lines are at ground potential and all other bit lines, source lines, or both are maintained at close to the negative erase potential.

Although only the ground potential and negative voltages are discussed in the above description, other voltages are possible, as electric potentials (i.e., voltages) are relative. For a memory device in a dual-gate memory string to be erased, according to the present invention, it is sufficient that an erase voltage is applied between the memory device's gate electrode (i.e., word line) and its bit line connection, source line connection, or both, while a voltage capable of forming an inversion channel is applied between the word lines controlling the gate electrodes of the access devices and the select devices and the bit line, source line, or both. Such an arrangement takes advantage of the structure of a dual-gate memory string formed by dual-gate memory cells. The structure allows the access devices of the memory string to connect any memory device in the memory string to be erased to a node (bit line, source line, or both) held at a more positive voltage than the voltage applied at the memory device's gate electrode.

In this way, the erase operations are fast, without at the same time requiring a special shorting connection between the source connection and the body of the thin-film devices in the memory string. Accordingly, the source voltage can be set at the best value to optimize channel boosting in the non-selected strings during programming. Also, the channels of these thin-film devices can be made thin and is optimized for device shrinking.

The above detailed description is provided to illustrate specific embodiments of the present invention and is not intended to be limiting. Numerous modifications and variations within the scope of the present invention are possible. The present invention is set forth in the accompanying claims.

I claim:

1. A method for erasing a first dual-gate memory cell in a memory string, the memory string comprises dual-gate memory cells connected by select devices to a bit line and a source line, each memory cell including an access device and a memory device sharing an active semiconductor region and connections to the bit line and the source line, the method comprising:
applying a first voltage to either the bit line or the source line;
applying a second voltage to gate electrodes of the access devices and select devices between that first dual-gate memory cell to be erased and the bit line or the source line to which the first voltage is applied, such that inversion channels are formed in the access devices and the select devices to connect the bit line or the source line to the bit line connection or the source line connection of that first dual-gate memory cell to be erased; and
applying a third voltage lower than the first voltage to the gate electrode of the memory device of that first dual-gate memory cell to be erased.

2. A method as in claim 1, wherein the memory string includes a second dual-gate memory cell to be erased, and wherein the second dual-gate memory cell is located between the first dual-gate memory cell to be erased and the bit line or the source line, the method further comprising applying the third voltage at the gate electrode of the second dual-gate memory device simultaneously with applying the third voltage at the gate electrode of the first dual-gate memory device.
